(19) United States
(12) Patent Application Publication
(10) Pub. No.: US 2012/0161240 A1
(43) Pub. Date: Jun. 28, 2012

(54) Transistor Comprising an Embedded Sigma-Shaped Semiconductor Alloy Having Superior Uniformity

(75) Inventors: Stephan Kronholz, Dresden (DE); Juergen Amon, Dresden (DE); Manfred Horstmann, Duerrroehrsdorf-Dittersbach (DE)

(73) Assignee: GLOBALFOUNDRIES INC., Grand Cayman (KY)

(21) Appl. No.: 13/337,690

(22) Filed: Dec. 27, 2011

(30) Foreign Application Priority Data
Dec. 28, 2010 (DE) 10 2010 064 284.3

(51) Int. Cl. H01L 27/088; H01L 21/336

(52) U.S. Cl. 257/368; 438/299; 438/285; 257/E21.409; 257/E27.06

(57) ABSTRACT

When incorporating a strain-inducing semiconductor alloy in one type of sophisticated transistors, the removal of sacrificial cap materials, such as a spacer layer, sacrificial spacer elements and dielectric cap materials, may be accomplished by using, at least in a first phase of the removal process, an efficient etch stop liner material, which may thus reduce the material loss in the drain and source extension regions that are formed prior to the deposition of the strain-inducing semiconductor material. Moreover, the drain and source extension regions of the other type of transistor may be formed with superior process uniformity due to a reduced material erosion of the corresponding spacer elements.

### BACKGROUND OF THE INVENTION

1. Field of the Invention

Generally, the present disclosure relates to the fabrication of integrated circuits, and, more particularly, to transistors having strained channel regions by using embedded semiconductor alloys, such as silicon/germanium, to enhance charge carrier mobility in the channel regions of the transistors.

2. Description of the Related Art

The fabrication of complex integrated circuits requires the provision of a large number of transistor elements, which represent the dominant circuit element for complex circuits. For example, several hundred millions of transistors may be provided in presently available complex integrated circuits. Generally, a plurality of process technologies are currently practiced, wherein, for complex circuitry, such as microprocessors, storage chips and the like, MOS technology is the most promising approach due to the superior characteristics in view of operating speed and/or power consumption and/or cost efficiency. In MOS circuits, field effect transistors, i.e., P-channel transistors and/or N-channel transistors, are used for forming circuit elements, such as inverters and other logic gates, to design highly complex circuit assemblies, such as CPUs, storage chips and the like. During the fabrication of complex integrated circuits using MOS technology, transistors are formed on a substrate including a crystalline semiconductor layer. A MOS transistor or generally a field effect transistor, irrespective of whether an N-channel transistor or a P-channel transistor is considered, comprises so-called PN junctions that are formed by an interface of highly doped drain and source regions with an inversely or weakly doped channel region disposed between the drain region and the source region. The conductivity of the channel region, i.e., the drive current capability of the conductive channel, is controlled by a gate electrode formed in the vicinity of the channel region and separated therefrom by a thin insulating layer. The conductivity of the channel region, upon formation of a conductive channel due to the application of an appropriate control voltage to the gate electrode, depends on, among other things, the dopant concentration, the mobility of the charge carriers and, for a given extension of the channel region in the transistor width direction, the distance between the source and drain regions, which is also referred to as channel length. Thus, the reduction of the channel length, and associated therewith the reduction of the channel resistivity, is a dominant design criterion for accomplishing an increase in the operating speed of the integrated circuits.

The continuing shrinkage of the transistor dimensions, however, involves a plurality of issues associated therewith that have to be addressed so as to not unduly offset the advantages obtained by steadily decreasing the channel length of MOS transistors. For example, highly sophisticated dopant profiles, in the vertical direction as well as in the lateral direction, are required in the drain and source regions to provide low sheet and contact resistivity in combination with desired channel controllability. Moreover, the gate dielectric material may also be adapted to the reduced channel length in order to maintain the required channel controllability. However, some mechanisms for maintaining high channel controllability may also have a negative influence on the charge carrier mobility in the channel region of the transistor, thereby partially offsetting the advantages gained by the reduction of the channel length.

Since the continuous size reduction of the critical dimensions, i.e., the gate length of the transistors, necessitates the adaptation and possibly the new development of highly complex process techniques and may also contribute to less pronounced performance gain due to mobility degradation, it has been proposed to enhance the channel conductivity of the transistor elements by increasing the charge carrier mobility in the channel region for a given channel length, thereby enabling a performance improvement that is comparable with the advance to a technology standard requiring extremely scaled critical dimensions, while avoiding or at least postponing many of the process adaptations associated with device scaling.

One efficient mechanism for increasing the charge carrier mobility is the modification of the lattice structure in the channel region, for instance by creating tensile or compressive stress in the vicinity of the channel region so as to produce a corresponding strain in the channel region, which results in a modified mobility for electrons and holes, respectively. For example, creating tensile strain in the channel region for a standard crystallographic configuration of the active silicon material, i.e., a (100) surface orientation with the channel length aligned to the <110> direction, increases the mobility of electrons, which, in turn, may directly translate into a corresponding increase in conductivity. On the other hand, compressive strain in the channel region may increase the mobility of holes, thereby providing the potential for enhancing the performance of P-type transistors. The introduction of stress or strain engineering into integrated circuit fabrication is an extremely promising approach, since strained silicon may be considered as a “new” type of semiconductor material, which may enable the fabrication of fast powerful semiconductor devices without requiring expensive semiconductor materials, while many of the well-established manufacturing techniques may still be used.

Consequently, it has been proposed to introduce, for instance, a silicon/germanium (Si/Ge) material next to the channel region so as to induce a compressive stress that may result in a corresponding strain. When forming the silicon/germanium material, the drain and source regions of the PMOS transistors are selectively recessed to form cavities, while the NMOS transistors are masked, and subsequently the silicon/germanium material is selectively formed in the cavities of the PMOS transistor by epitaxial growth.

Generally, the concept of incorporating a strain-inducing silicon/germanium material into the active region of P-channel transistors is a very promising approach, which significantly contributes to superior performance of the P-channel transistors. The efficiency of the strain-inducing mechanism strongly depends on the mismatch of the natural lattice constants of the silicon/germanium alloy and the silicon base material. Consequently, great efforts are being made in providing the silicon/germanium alloy with high germanium concentration, which, however, may be limited by presently available selective epitaxial growth techniques so that it is difficult to achieve a germanium concentration of approximately 30 atomic percent and higher. Moreover, the strain in the channel region may be increased by reducing the offset of the silicon/germanium material from the channel region and also the depth of the cavities and, thus, of the semiconductor alloy may also influence the finally obtained strain in the channel region. Consequently, a plurality of promising approaches have been developed in order to individually or commonly improve one or more of the above-specified parameters in order to increase the overall strain in the channel region. At the same time, the shrinkage of the gate length and thus of the overall transistor dimensions is continued in an attempt to further increase the overall packing density and performance of complex semiconductor devices. It turns out, however, that significant fluctuations in transistor parameters may be observed when implementing the above-described approach for incorporating a strain-inducing silicon/germanium material into highly scaled transistor devices, as will be described in more detail with reference to FIGS. 1a-1e.

FIG. 1a schematically illustrates a cross-sectional view of a semiconductor device 100 comprising a substrate 101 and a semiconductor layer 102, in which a plurality of active regions are laterally delineated by appropriate isolation structures. For convenience, a first active region 102A corresponding to a P-channel transistor and a second active region 102B corresponding to an N-channel transistor are illustrated so as to be laterally separated by an isolation region 102C. Generally, an active region is to be understood as a semiconductor region, such as a silicon region, in which appropriate PN junctions have to be provided so as to form one or more transistor elements in and above the corresponding active region. In the manufacturing stage shown, a first gate electrode structure 160A is formed on the active region 102A and comprises a gate dielectric material 161 and an electrode material 162. The gate dielectric material 161 typically comprises a silicon oxide-based dielectric material, possibly in combination with a high-k dielectric material, if required. Similarly, the electrode material 162 may comprise polysilicon and the like. Furthermore, a dielectric cap layer or cap layer system 164, which is essentially comprised of silicon nitride, is formed on the electrode material 162. Moreover, a spacer 165 is formed on sidewalls of the gate electrode structure 160A, possibly in combination with an additional liner 163. The spacer 165 may be comprised of silicon dioxide with a width that is appropriate to perform implantation processes for forming an appropriate dopant profile in the active regions 102A, 102B. For example, the spacer 165 may have a width of approximately 6-10 nm, while a length of the gate electrode structure 160A, i.e., in FIG. 1a the horizontal extension of the electrode material 162, may be 50 nm and less, for instance 30 nm and less in highly sophisticated applications.

Similarly, a second gate electrode structure 160B is formed on the active region 102B and may comprise basically the same components as the gate electrode structure 160A. Moreover, in the stage shown, drain and source extension regions 151E are selectively provided in the first active region 102A, in combination with any counter-doped regions (not shown), which are typically referred to as halo regions, and which may be used for adjusting basic transistor characteristics such as threshold voltage and the like.

The semiconductor device 100 as illustrated in FIG. 1a may be formed on the basis of the following processes. The active regions 102A, 102B may be laterally delineated by forming the isolation region 102C by using sophisticated lithography techniques, etch processes, deposition sequences and anneal and planarization techniques. Prior to or after forming the isolation region 102C, appropriate well dopant species may be incorporated into the active regions 102A, 102B by using well-established masking regimes and implantation techniques. Thereafter, appropriate material layers may be deposited or otherwise formed in order to obtain an appropriate gate layer stack, which comprises the materials of the layers 161, 162, 164 and possibly any other material layers that may be required for performing a complex sequence of lithography processes in combination with etch processes so as to pattern the gate electrode structures 160A, 160B on the basis of the given design requirements. It should be appreciated that typically the dielectric cap layer 164 may be used as an efficient hard mask material and may also be used as a cap material during the further processing of the device. Thereafter, the liners 163 may be formed, for instance, by oxidation, if required, followed by the deposition of an oxide material with highly controlled thickness, followed by a subsequent etch process in order to form the spacer elements 165 having the desired width. Thereafter, the active region 102B and the gate electrode structure 160B may be masked in order to introduce dopant species selectively into the active region 102A, thereby forming the extension regions 151E and any counter-doped region in accordance with the overall transistor characteristics. Thereafter, an anneal process may be performed so as to activate the dopants and reduce any implantation-induced crystal damage.

FIG. 1b schematically illustrates the device 100 in a further advanced manufacturing stage. As illustrated, a spacer layer 166 covers the active region 102B and the gate electrode structure 160B, wherein the layer 166 is patterned into a sacrificial spacer element 166S that is formed on the spacer 165 in the gate electrode structure 160A. To this end, the spacer layer 166 is deposited in the form of a silicon nitride material on the basis of well-established deposition techniques, followed by a lithography step for forming a resist mask 108 above the active region 102B. Thereafter, well-established anisotropic etch recipes are applied in order to etch the exposed portion of the layer 166, thereby finally forming the spacer 166S. It should be appreciated that the spacer 166S may strongly influence the transistor characteristics since it may determine the lateral offset of a cavity to be formed in the active region 102A so as to form therein the strain-inducing silicon/germanium alloy. During the corresponding etch process for patterning the spacer 166S, the etch chemistry may be appropriately adapted so as to etch into the active region 102A.

FIG. 1c schematically illustrates the device 100 in a manufacturing stage in which a cavity 103 is to be formed in the active region 102A, possibly based on the etch mask 108 of FIG. 1b or by using the spacer layer 166 as an efficient etch mask. For example, when applying highly anisotropic etch techniques, the cavity 103 may have relatively steep sidewalls, the lateral offset of which is determined by the spacer 166S. After the etch process for forming the cavity 103, additional cleaning recipes are applied and thereafter a selective epitaxial growth process is performed on the basis of well-established recipes in order to grow a silicon/germanium alloy in the cavities 103. As discussed above, generally, an increased germanium concentration may result in superior strain characteristics, wherein, however, currently available deposition recipes may result in increased lattice defects when increasing the germanium concentration above approximately 30 atomic percent. On the other hand, incorporating a dopant species, such as boron, may increase the concentration of germanium that may be incorporated into the selectively grown material without unduly contributing to the overall defect rate. On the other hand, the incorporation of a moderately high in situ dopant concentration may result in increased variability of transistor characteristics, since the silicon/germanium alloy may be exposed to various reactive process atmospheres, which may result in a certain degree of material erosion.

FIG. 1d schematically illustrates the semiconductor device 100 in a manufacturing stage in which a silicon/germanium alloy 152 is formed in the active region 102A. Moreover, the dielectric cap layers 164, the spacer layer 166 and the spacers 166S (see FIG. 1c) have been removed. To this end, efficient wet chemical etch recipes are applied on the basis of hot SPM (sulfuric acid/hydrogen peroxide mixture), wherein, however, due to a pronounced over-etch time in order to reliably remove the spacer layer 166 from above the active region 102B, a certain degree of material erosion may occur, for instance, in the active region 102A and in particular in the silicon/germanium material 152, since germanium may preferably be oxidized by hot SPM. Furthermore, the spacers 165 may suffer from a certain degree of material erosion during the preceding wet chemical etch process, thereby resulting in a less predictable final width of the spacers 165, which are then used as an implantation mask for incorporating dopant species, forming the drain and source extension regions 151E in the second active region 102B and also for forming any counter-doped areas. Consequently, in the active region 102A, a more or less pronounced loss of material, as indicated by 104, may reduce the overall efficiency of the strain-inducing effect of the material 152. Moreover, in other sophisticated approaches, previously a cavity 105 may be provided on the basis of a well-controllable crystallographically anisotropic etch technique, in which specific crystal planes may act as efficient etch stop planes. In this manner, a very controlled lateral etch rate may be achieved, since the corresponding inclined crystal planes may finally essentially suppress a further lateral advance of the etch process. Thus, in this case a well-defined lateral offset of the material 152 may be adjusted, wherein, however, in this case, a pronounced material loss may even further influence the transistor characteristics due to the close proximity to a channel region 153. Furthermore, in many approaches, the material 152 may be provided in the form of an in situ doped material, so that any non-predictable material loss may even further contribute to a variability of the resulting transistor characteristics.

Similarly, the dopant profile of any counter-doped regions in the active region 102B and the associated extension regions 151E may suffer from increased variability due to the material erosion of the spacer element 165.

FIG. 1e schematically illustrates the semiconductor device 100 in a further advanced manufacturing stage. As shown, the spacer structures 160A, 160B comprise a further spacer structure 167, which in combination with a spacer 165 are used to adjust the final dopant profile of drain and source regions 151 of transistors 150A, 150B. The spacer structures 167 and the drain and source regions 151 may be formed on the basis of well-established deposition and anisotropic etch techniques, followed by an appropriate implantation sequence in combination with an appropriate masking regime. Thereafter, any further anneal processes are performed so as to adjust the final lateral and vertical dopant profile. Thereafter, if required, metal silicide materials (not shown) may be formed in the gate electrode structures 160A, 160B and the drain and source regions 151 by any well-established process strategy.

Thus, after completing the basic transistor configuration of the devices 150A, 150B, the above-described process non-uniformities, in particular upon forming the strain-inducing semiconductor material 152 in the presence of the sacrificial spacer elements, which are subsequently removed in combination with the residual spacer layer and the dielectric cap materials, also significantly contribute to variabilities of transistors 150A, 150B, which may even further contribute to yield loss when overall device dimensions are reduced. That is, since the corresponding process-induced non-uniformities may not scale in the same manner as the device dimensions, an increased influence of these non-uniformities may be observed upon further reducing the overall critical dimensions.

In view of the situation described above, the present disclosure relates to semiconductor devices and manufacturing techniques in which a strain-inducing semiconductor alloy may be formed in one type of transistor, while avoiding or at least reducing the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present disclosure generally provides semiconductor devices and manufacturing techniques in which a strain-inducing semiconductor alloy, such as silicon/germanium, may be formed selectively in the active region of one type of transistor while masking the active regions of other transistors on the basis of a spacer layer, which may be efficiently removed in a later manufacturing stage together with any sacrificial spacer elements by using efficient etch techniques and an etch stop liner. Consequently, in this manner, non-uniform material loss, in particular in the drain and source extension region formed prior to the deposition of the strain-inducing semiconductor alloy, may be significantly reduced. Consequently, highly sophisticated approaches may be selected in order to provide superior strain efficiency, for instance by using etch techniques with a significant lateral etch rate upon forming the cavities for the strain-inducing semiconductor alloys, in situ doping techniques and the like, since the superior controllability upon removing, in particular, the remaining spacer layer may thus also reduce resulting variability of transistor characteristics, such as threshold voltage variations and the like. Moreover, any non-uniformities of initial spacer elements, which may be used for incorporating the drain and source extension regions for transistors in a later manufacturing stage, may also be reduced, thereby providing superior uniformity of the transistors which may not require the incorporation of the strain-inducing semiconductor material. Consequently, in total, highly sophisticated strain-inducing mechanisms may be implemented without unduly affecting the overall transistor variability of both types of transistor.

One illustrative method disclosed herein comprises forming a first gate electrode structure on a first active region and a second gate electrode structure on a second active region, wherein the first and second gate electrode structures comprise a first spacer and a dielectric cap layer. The method further comprises forming an etch stop liner above the first and second gate electrode structures and forming a second spacer from a spacer layer selectively on the first gate electrode structure and preserving the spacer layer above the second gate electrode structure and the second active region. Moreover, the method comprises forming a strain-inducing semiconductor material in the first active region and using the second spacer as a mask, wherein the strain-inducing semiconductor material extends below the second spacer. The method further comprises removing the spacer layer and the second spacer and using the etch stop liner as an etch stop. Moreover, the dielectric cap layers in the first and second gate electrode structures are removed and drain and source regions are formed in the first and second active regions.

A further illustrative method disclosed herein relates to forming an embedded strain-inducing semiconductor alloy selectively in a transistor. The method comprises forming a first spacer on a first gate electrode structure and a second gate electrode structure, wherein the first gate electrode structure is formed on a first active region and the second gate electrode structure is formed on a second active region. Moreover, drain and source extension regions are selectively formed in the first active region by using the first gate electrode structure as a mask. Furthermore, the method comprises forming a spacer layer stack above the first and second gate electrode structures, wherein the spacer layer stack comprises a spacer layer and an etch stop liner. Moreover, a second spacer is formed from the spacer layer selectively on the first gate electrode structure, while the spacer layer stack is preserved above the second gate electrode structure. Furthermore, a cavity is formed in the first active region by using the second spacer as a mask and the strain-inducing semiconductor alloy is epitaxially grown in the cavity. Additionally, the second spacer and the spacer layer are removed selectively to the etch stop liner.

One illustrative semiconductor device disclosed herein comprises a first gate electrode structure formed on a first active region and comprising a first inner spacer and a first outer spacer. The semiconductor device further comprises a second gate electrode structure formed on a second active region and comprising a second inner spacer and a second outer spacer, wherein the first inner spacer has a width that is less than a width of the second inner spacer. The semiconductor device further comprises a semiconductor alloy formed in the first active region and having inclined sidewalls at a side positioned adjacent to a channel region, wherein an inclination angle of the inclined sidewalls is defined by crystal planes of the first active region. The semiconductor device further comprises first drain and source regions formed in the first active region and having a first conductivity type and second drain and source regions formed in the second active region and having a second conductivity type that is different from the first conductivity type.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1e schematically illustrate cross-sectional views of a semiconductor device when incorporating a strain-inducing semiconductor alloy in sophisticated devices selectively in P-channel transistors, according to conventional approaches; and

FIGS. 2a-2h schematically illustrate cross-sectional views of a semiconductor device during various manufacturing stages in forming an embedded strain-inducing semiconductor alloy selectively in one type of transistor, while removing a growth mask and a dielectric cap material with superior process uniformity, according to illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally contemplates semiconductor devices and manufacturing techniques in which the removal of sacrificial materials used during the incorporation of a strain-inducing semiconductor material in one type of transistor may be accomplished with superior process uniformity and controllability by providing an appropriate liner material prior to forming the sacrificial spacer layer from which the sacrificial spacer elements are to be formed. Consequently, upon patterning the sacrificial spacer layer, and in particular upon removing the sacrificial spacers and the remaining portion of the spacer layer, the liner material may act as an efficient etch stop liner, thereby avoiding undue interaction of the etch chemistry with sensitive device areas, such as drain and source extension regions, inner sidewall spacers and the like. Due to the superior controllability of the removal process and of finally exposing the gate electrode structures, any sophisticated approaches may be applied in order to incorporate the strain-inducing semiconductor alloy, since the degree of non-uniformity, which may conventionally directly translate into device non-uniformities in an over-proportional manner, may be significantly reduced.

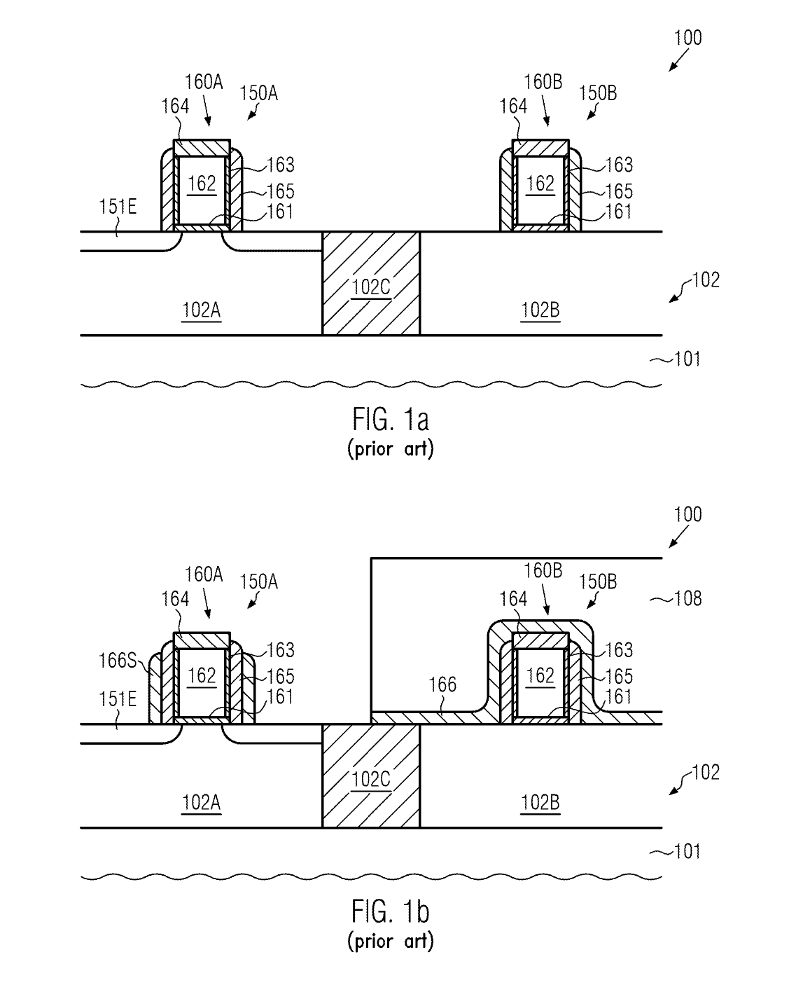

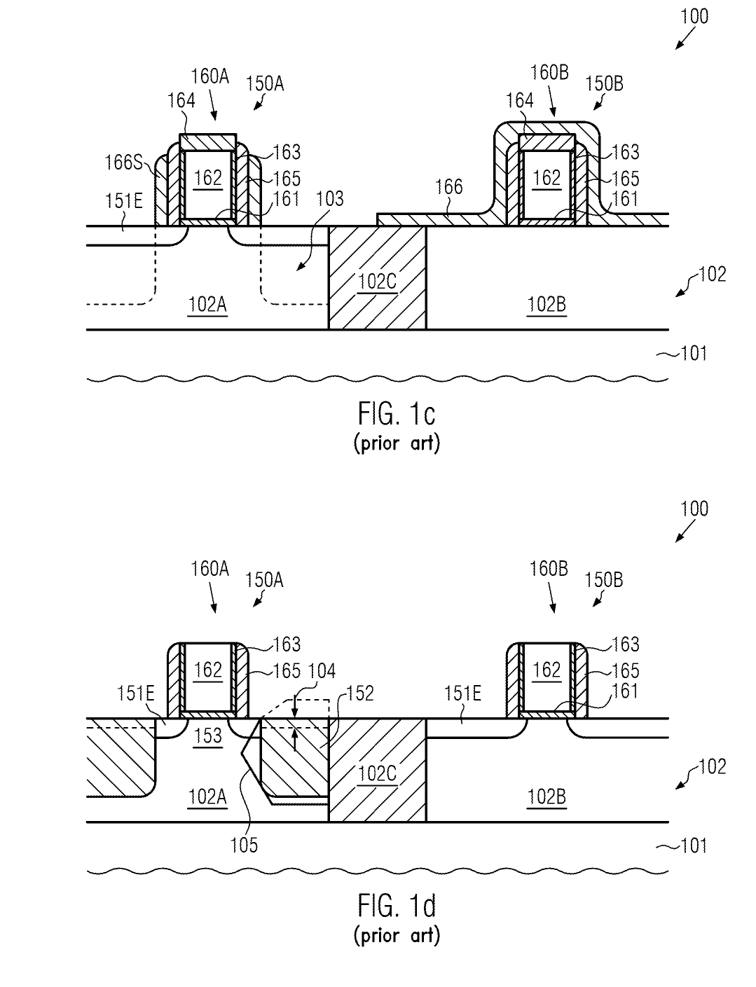

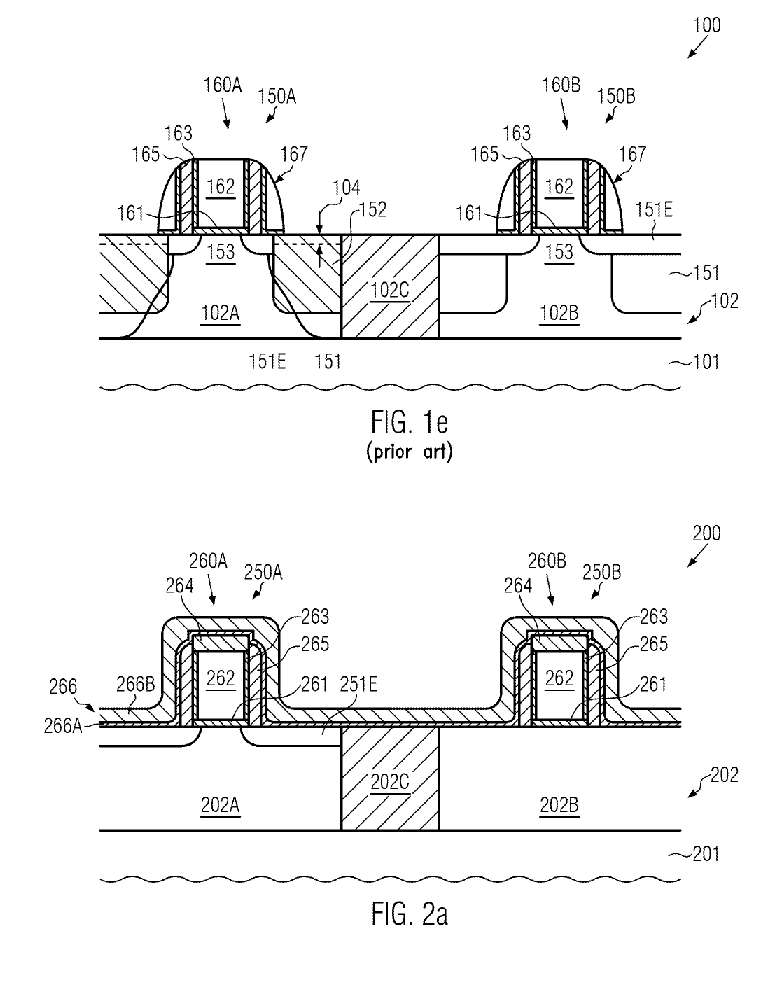

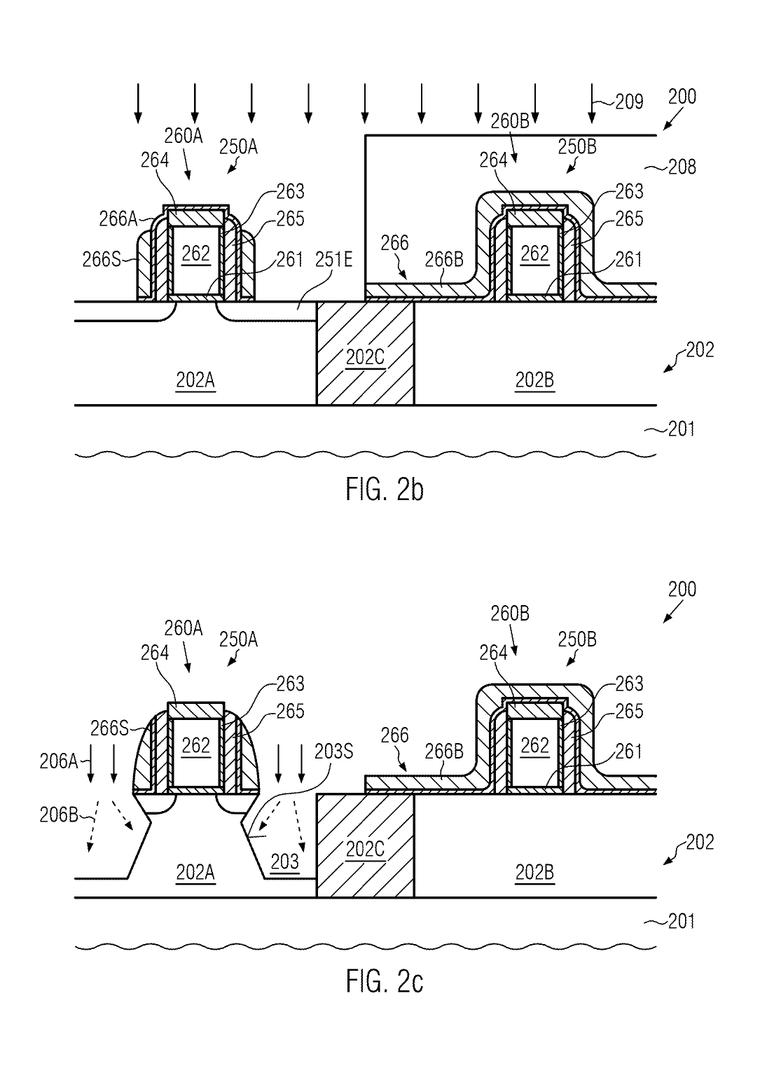

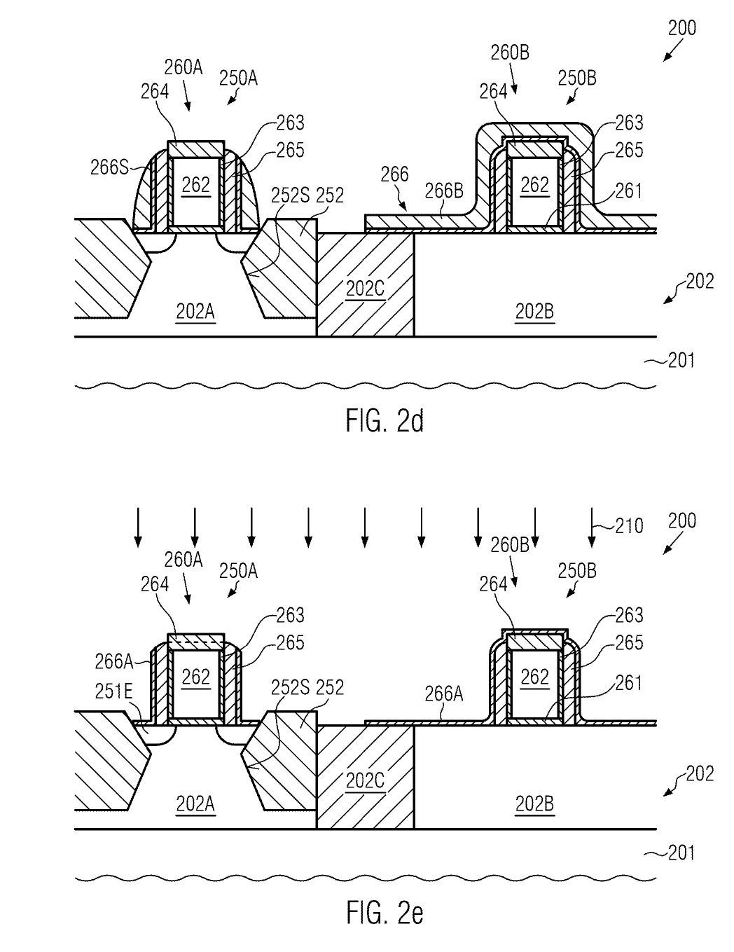

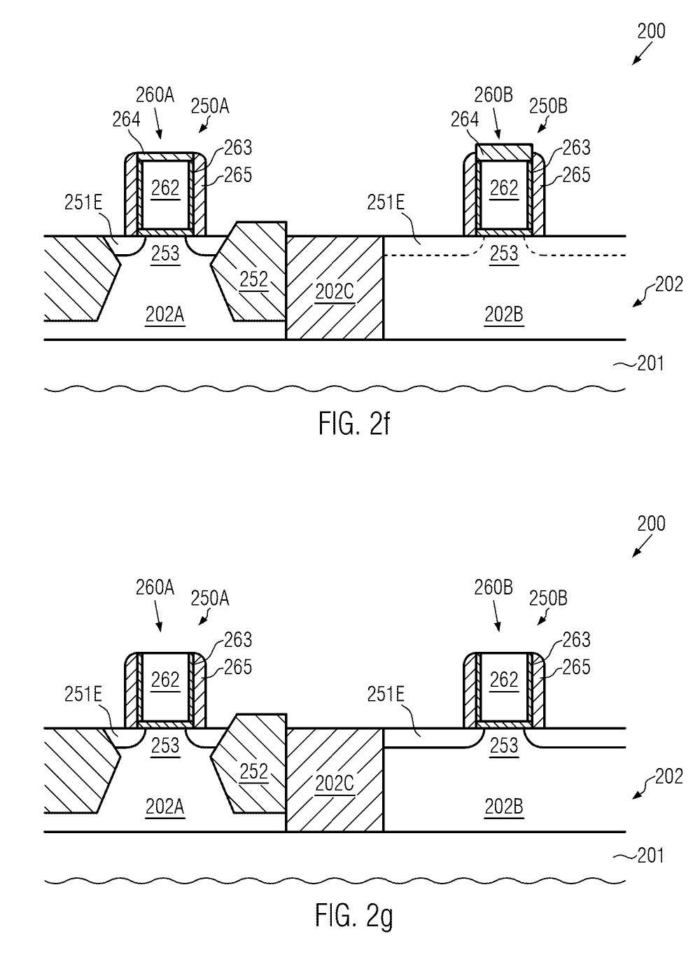

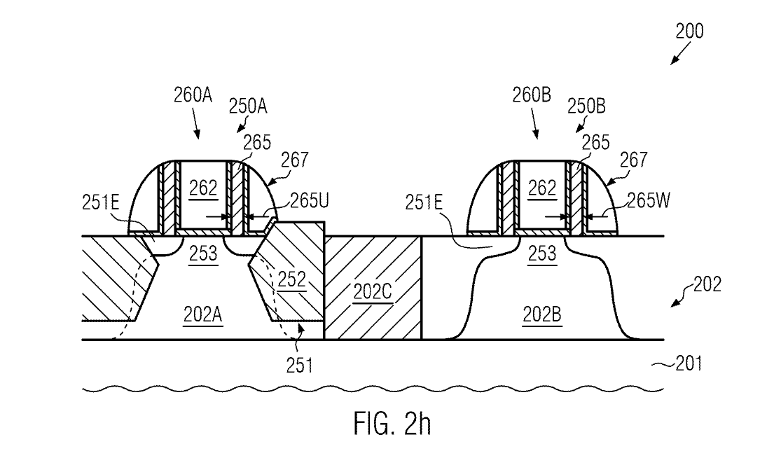

With reference to FIGS. 2a-2h, further illustrative embodiments will now be described in more detail, wherein reference may also be made to FIGS. 1a-1e, if required.

FIG. 2a schematically illustrates a cross-sectional view of a semiconductor device 200 comprising a substrate 201 and a semiconductor layer 202, in which a plurality of active regions may be laterally delineated by an isolation region 202C. For example, a first active region 202A and a second active region 202B are separated by the isolation region 202C. Furthermore, the substrate 201 and the semiconductor layer 202 may form a bulk configuration in which the active region 202B may directly connect to a crystalline material of the substrate 201, while, in other cases, an SOI (silicon-on-insulator) configuration may be provided in which a buried insulating material (not shown) is formed below the semiconductor layer 202. Furthermore, in the manufacturing stage shown, a gate electrode structure 260A is formed on the active region 202A and a gate electrode structure 260B is formed on the active region 202B. The gate electrode structures 260A, 260B may have basically the same configuration and may comprise a gate dielectric material 261, an electrode material 262, followed by a dielectric cap layer 264. Moreover, if required, a liner 263 may be formed on sidewalls of the gate electrode structures 260A, 260B, followed by a spacer 265, which may have an appropriate width so as to act as an efficient implantation mask for incorporating dopant species for forming drain and source extension regions and any counter-doped regions into the active regions 202A, 202B at any appropriate manufacturing stage.

It should be appreciated that, with respect to these components, the same criteria may apply as previously put forward in the context of the semiconductor device 100. Furthermore, the semiconductor device 200 may comprise a spacer layer stack 266, which may comprise at least an etch stop liner 266A and a spacer layer 266B. In some illustrative embodiments, the etch stop liner 266A may be comprised of silicon dioxide, while the spacer layer 266B may be comprised of silicon nitride. It should be appreciated, however, that any other material system may be used as long as the spacer layer 266B may be efficiently etched selectively with respect to the material 266A. Moreover, the spacer layer stack 266 may be provided with an appropriate initial thickness in order to obtain an appropriate spacer width after patterning the layer stack 266 into a sacrificial spacer selectively above the active region 202A. For example, a total thickness of the spacer layer stack 266 may be in the range of approximately 5-10 nm, wherein, for instance, the liner 266A may have a thickness of 2-5 nm. It should be appreciated, however, that corresponding thickness values may refer to an average thickness, since certain variability may exist due to the overall surface topography of the device 200 in this manufacturing stage. Furthermore, drain and source extension regions 251E are formed in the first active region 202A so as to have a desired lateral and vertical profile.

The semiconductor device 200 as shown in FIG. 2a may be formed on the basis of manufacturing techniques as are also previously discussed with reference to the semiconductor device 100 in the context of FIG. 1a. Contrary to the conventional approaches, the further processing may be continued after the annealing of the drain and source extension regions 251E and of any halo regions (not shown) by depositing the layer stack 266, which may be accomplished by any appropriate deposition techniques, such as plasma enhanced CVD (chemical vapor deposition), thermally activated CVD and the like.

FIG. 2b schematically illustrates the semiconductor device 200 in a further advanced manufacturing stage. As shown, the spacer layer stack 266 is substantially preserved above the active region 202B, while a spacer 266S is formed from the spacer layer 266B, which may be accomplished on the basis of an anisotropic etch process 209 in which the material of the layer 266B is removed selectively with respect to the liner 266A. On the other hand, the spacer layer stack may be covered by a resist mask 208. At any appropriate phase of the etch process 209 or in a dedicated etch step (not shown), any exposed portions of the layer 266A above the first active region 202A may be removed so as to provide the device 200 for a further etch step for etching into the active region 202A. The exposed portions of the etch stop liner 266A may be removed, for instance, by wet chemical etch steps, plasma assisted etch recipes and the like. For example, a plurality of etch recipes are available for removing a silicon dioxide material selectively with respect to silicon nitride, silicon and the like.

FIG. 2c schematically illustrates the semiconductor device 200 in a further advanced manufacturing stage. As illustrated, cavities 203 may be formed in the active region 202A and may have respective sidewall surface areas 2035, which may extend below the sacrificial spacer 266S. That is, the spacers 266S may be “under-etched” to a certain degree in order to reduce the lateral offset of a strain-inducing semiconductor alloy to be formed in the cavities 203. To this end, an etch sequence may be applied, for instance, by first performing a plasma assisted anisotropic etch process 206A in order to form respective recesses down to a specified depth, followed by a further etch process 206B, which may also have a pronounced lateral etch rate. As previously explained, in some illustrative embodiments, a crystallographically anisotropic etch process may be performed wherein respective crystal planes, such as (111) planes, may act as efficient “etch stop” planes. Hence, the sidewalls 203S may be formed as inclined sidewalls having an inclination angle that is determined by the crystallographic configuration of the active region 202A. For example, a (111) plane or physically equivalent planes form a well-defined angle. The etch step 206B may be performed on the basis of appropriate wet chemical etch chemistries, for instance using TMAH (tetra methyl ammonium hydroxide) and the like. Consequently, by adjusting a depth of the cavities 203 during the first anisotropic etch process 206A, further etching may be continued on the basis of well-controllable etch conditions due to the self-limiting lateral etch behavior of the process 206B.

FIG. 2d schematically illustrates the semiconductor device 200 in a further advanced manufacturing stage in which a strain-inducing semiconductor alloy may be formed in the cavities 203 (FIG. 2c) thereby obtaining, in the embodiment shown, also inclined sidewall surface areas 252S. In some illustrative embodiments, the material 252 may be a compressive strain-inducing semiconductor alloy, which may be accomplished by using a silicon/germanium alloy, a silicon/tin alloy, a silicon/germanium/tin alloy in combination with a silicon base material in the active region 202A. In other illustrative embodiments, a tensile strain may be induced, for instance by providing the material 252 as a silicon/carbon alloy. Generally, the material 252 may be provided on the basis of well-established selective epitaxial growth techniques wherein, in some illustrative embodiments, a desired type of dopant may be incorporated into the deposition atmosphere in order to obtain a desired degree of in situ doping. As discussed above, the in situ doping, for instance the incorporation of a boron species, may enable providing a higher germanium concentration, which in turn may directly translate into superior performance of a transistor to be formed in and above the active region 202A. On the other hand, the sensitivity to any process fluctuations during the further processing of the device 200 may be significantly reduced due to the presence of the etch stop liner 266A.

FIG. 2e schematically illustrates the device 200 during an etch process 210 in order to remove at least the sacrificial layer 266B from above the active region 202B. In some illustrative embodiments, the process 210 may be performed on the basis of a wet chemical etch recipe, such as hot SPM, which may efficiently remove silicon nitride selectively with respect to silicon dioxide so that the remaining portion of the etch stop liner 266A may thus protect any underlying components, such as the spacer 265, in particular above the second active region 202B. Moreover, the etch stop liner 266A may also protect the remaining portion of the drain and source extension regions 251E in the active region 202A, thereby also significantly reducing any undesired material loss. On the other hand, a certain degree of material loss of the material 252 may be acceptable, since the corresponding loss may be compensated for by appropriately selecting the initial height of the material 252. This may be accomplished by generally a superior controllability of the overall process flow for forming the material 252 may be accomplished, for instance when using the crystallographically anisotropic etch process for adjusting the size and shape of the cavities, as is also discussed above with reference to FIG. 2c. It should be appreciated that during the etch process 210 the cap layer 264 may be reduced in thickness or may be completely removed, depending on the overall process time selected for the process 210.

FIG. 2f schematically illustrates the device 200 in a further advanced manufacturing stage in which the etch stop liner 266A (FIG. 2e) is removed, which may be accomplished by using any well-established etch chemistries, such as diluted HF (hydrofluoric acid) and the like. Typically, the etch chemistry may have a high selectivity with respect to silicon material, thereby also not unduly removing material of the drain and source extension regions 251E. Moreover, to reduce the thickness of the etch stop liner 266A (FIG. 2e), highly controllable etch processes may be accomplished, thereby also providing a very predictable and reduced material loss of the spacers 265, in particular in the gate electrode structure 260B, since this spacer has been completely covered by the etch stop liner 266A when removing the spacer layer 266B (FIG. 2d). In some illustrative embodiments, in this manufacturing stage, an implantation process may be performed so as to incorporate dopant species into the active region 202B, while masking the active region 202A, thereby, for instance, forming the drain and source extension regions 251E in combination with any counter-doped or halo regions (not shown). In this case, the remaining cap layer 264 in the gate electrode structure 260B may provide a superior ion blocking effect, in particular during a corresponding halo implantation process, which may contribute to superior integrity of sensitive device areas, such as the channel region 253.

FIG. 2g schematically illustrates the device 200 in a further advanced manufacturing stage in which the cap layer 264 of the gate electrode structure 260B and possibly a remaining portion of the cap layer 264 of the gate electrode structure 260A may be removed, for instance based on wet chemical etch recipes, as is also previously discussed. Although in this stage of the process, a certain degree of material loss may occur in the drain and source extension regions 251E in the active region 202A, a corresponding amount is significantly reduced compared to conventional strategies since the exposure to any reactive process atmosphere is significantly less, since any other sacrificial materials, such as the spacer layer 266B (FIG. 2d), have been removed in an earlier manufacturing stage substantially without contributing to a material loss in the drain and source regions 251E. It should be appreciated that, in some illustrative embodiments, the drain and source extension regions 251E, in combination with any halo regions, in the second active region 202B may be formed after the removal of the cap layer, thereby providing a high degree of compatibility with conventional process strategies.

FIG. 2h schematically illustrates the semiconductor device 200 in a further advanced manufacturing stage. As shown, drain and source regions 251 are formed in the active regions 202A, 202B in accordance with the overall transistor requirements. For example, a transistor 250A may represent a P-channel transistor or an N-channel transistor, while the transistor 250B may represent a transistor of inverse conductivity type. For example, the transistor 250A may represent a transistor requiring a compressive strain component in the channel region 253 in order to provide superior performance. Furthermore, the gate electrode structures 260A, 260B may comprise a further sidewall spacer structure 267, which may be used for defining the lateral dopant profile of the corresponding drain and source regions 251. In other cases, the drain and source regions 251 may be substantially defined by an in situ doping of the material 252, as previously discussed. In this case, the drain and source extension regions 251E of the transistor 250A may appropriately connect to the material 252, which may in turn include desired in situ concentration of an appropriate dopant species. In other cases, additionally or alternatively to providing an in situ doped material 252, further drain and source dopant species may be incorporated by ion implantation techniques. Similarly, the transistor 250B may comprise the drain and source regions 251 including the extension regions 251E, which may have superior uniformity compared to conventional strategies due to the superior uniformity of the spacers 265, as is also discussed. Moreover, a width 265W of these spacer elements of the spacer 265 of the transistor 250B may be greater compared to the final spacer width 265U in the transistor 250A due to the superior confinement obtained on the basis of the etch stop liner, as is also discussed above.

Generally, the transistors 250A, 250B may be formed on the basis of any appropriate process strategy, as is also discussed above with reference to the semiconductor device 100.

As a result, the present disclosure provides semiconductor devices and manufacturing techniques in which the removal of any sacrificial materials required for the incorporation of the strain-inducing semiconductor material in one type of transistor may be accomplished with superior controllability, thereby reducing any material loss in sensitive device areas, such as the drain and source extension regions of the transistor under consideration. On the other hand, also superior uniformity of the spacer structure used for forming the drain and source extension regions of the other type of transistor may be accomplished, thereby generally providing superior transistor characteristics, while at the same time sophisticated process techniques may be applied in forming the strain-inducing semiconductor material. That is, a desired high degree of in situ doping, possibly in combination with increased germanium concentration, may be applied on the basis of crystallographically anisotropically etched cavities.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a first gate electrode structure on a first active region and a second gate electrode structure on a second active region, said first and second gate electrode structures comprising a first spacer and a dielectric cap layer;
forming an etch stop liner above said first and second gate electrode structures;
forming a second spacer from a spacer layer selectively on said first gate electrode structure and preserving said spacer layer above said second gate electrode structure and said second active region;
forming a strain-inducing semiconductor material in said first active region and using said second spacer as a mask, said strain-inducing semiconductor material extending below said second spacer;
removing said spacer layer and said second spacer and using said etch stop liner as an etch stop;
removing said dielectric cap layer in said first and second gate electrode structures; and
forming drain and source regions in said first and second active regions.

2. The method of claim 1, wherein forming said strain-inducing semiconductor material comprises forming a cavity by performing a crystallographically anisotropic etch process and growing said strain-inducing semiconductor material at least on said cavity.

3. The method of claim 2, wherein forming said cavity further comprises performing a plasma based anisotropic etch process prior to performing said crystallographically anisotropic etch process.

4. The method of claim 1, wherein forming said strain-inducing semiconductor material comprises epitaxially growing said strain-inducing semiconductor material and incorporating a drain and source dopant species into the growth ambient.

5. The method of claim 1, further comprising forming drain and source extension regions selectively in said first active region by using said first spacer as a mask.

6. The method of claim 1, further comprising forming drain and source extension regions selectively in said second active region after removing said spacer layer.

7. The method of claim 6, wherein said drain and source extension regions in said second active region are formed prior to removing said dielectric cap layer of said first and second gate electrode structures.

8. The method of claim 6, wherein said drain and source extension regions in said second active region are formed after removing said dielectric cap layer of said first and second gate electrode structures.

9. The method of claim 1, wherein said strain-inducing semiconductor material is formed so as to induce a compressive strain.

10. The method of claim 1, wherein said first and second active regions are formed so as to have an inverse conductivity type with respect to each other.

11. The method of claim 1, further comprising performing an etch process so as to remove said etch stop liner after removing said second spacer and said spacer layer.

12. A method of forming an embedded strain-inducing semiconductor alloy selectively in a transistor, the method comprising:
forming a first spacer on a first gate electrode structure and a second gate electrode structure, said first gate electrode structure being formed on a first active region, said second gate electrode structure being formed on a second active region;
forming drain and source extension regions selectively in said first active region by using said first gate electrode structure as a mask;
forming a spacer layer stack above said first and second gate electrode structures, said spacer layer stack comprising a spacer layer and an etch stop liner;
forming a second spacer from said spacer layer selectively on said first gate electrode structure while preserving said spacer layer stack above said second gate electrode structure;
forming a cavity in said first active region by using said second spacer as a mask;
epitaxially growing said strain-inducing semiconductor alloy in said cavity; and
removing said second spacer and said spacer layer selectively to said etch stop liner.

13. The method of claim 12, further comprising removing a dielectric cap layer provided on said first and second gate electrode structures after removing said second spacer and said spacer layer.

14. The method of claim 12, wherein forming said cavity comprises performing an etch process so as to under-etch at least a portion of said second spacer.

15. The method of claim 14, wherein performing said etch process comprises performing a wet chemical etch process that has a crystallographically anisotropic etch behavior.

16. The method of claim 12, further comprising forming drain and source extension regions in said second active region on the basis of said first spacer after removing said spacer layer.

17. The method of claim 12, wherein epitaxially growing said strain-inducing semiconductor alloy comprises incorporating a drain and source dopant species.

18. The method of claim 17, wherein said semiconductor alloy induces a compressive strain and said drain and source dopant species is a P-type dopant species.

19. A semiconductor device, comprising:
a first gate electrode structure formed on a first active region, said first gate electrode structure comprising a first inner spacer and a first outer spacer;
a second gate electrode structure formed on a second active region, said second gate electrode structure comprising a second inner spacer and a second outer spacer, said first inner spacer having a width that is less than a width of said second inner spacer;
a semiconductor alloy formed in said first active region and having inclined sidewalls at a side that is positioned adjacent to a channel region, an inclination angle of said inclined sidewalls being defined by crystal planes of said first active region;
first drain and source regions formed in said first active region and having a first conductivity type; and
second drain and source regions formed in said second active region and having a second conductivity type other than said first conductivity type.

20. The semiconductor device of claim 19, wherein a length of said first and second gate electrode structures is 30 nm or less.
